(19) United States
(12) Patent Application Publication
(10) Pub. No.: US 2025/0261460 A1
(43) Pub. Date: Aug. 14, 2025

(54) IMAGE SENSOR WITH ASYMMETRIC SOURCE FOLLOWER DOPING PROFILE FOR HIGH CONVERSION GAIN

(71) Applicant: Fairchild Imaging, Inc., San Jose, CA (US)

(72) Inventors: Xianmin Yi, Menlo Park, CA (US); Alexander Lu, San Jose, CA (US)

(21) Appl. No.: 18/437,820

(22) Filed: Feb. 9, 2024

(51) Int. Cl. H01L 27/146

(52) U.S. Cl. CPC H10F 39/80377; H10F 39/18

(57) ABSTRACT

An image sensor pixel array includes a source follower transistor configured with an asymmetric doping profile under its gate. In an example, a given pixel of a pixel array includes a photodetector coupled to a readout circuit, which includes a transfer gate between the photodetector and a source follower transistor. In an example, the source follower transistor includes doped source and drain regions with a lightly doped drain (LDD) region adjacent to the source region, but no corresponding LDD region adjacent to the drain region. Such a configuration allows for reduced parasitic capacitance across the gate-drain junction of the transistor, which provides a higher conversion gain for the pixel.

### BACKGROUND

Image sensors are widely used for a number of different applications across a large portion of the electromagnetic spectrum. Many image sensor designs use an array of sensors to capture light across a given area. Each sensor may be considered a single pixel of the sensor array, with the pixels arranged in any number of rows and columns. Each pixel includes a photodetector as well as a circuit to collect the charge from the photodetector in response to a light input. A number of non-trivial issues exist with regard to the design of the sensor circuit to provide both a high dynamic range and a high conversion gain.

### BRIEF DESCRIPTION OF THE DRAWINGS

FIG. 1 is a block diagram of an image sensor that uses a pixel array, in accordance with an embodiment of the present disclosure.

FIG. 2 is a block diagram illustrating components of a single pixel of the pixel array of FIG. 1, in accordance with an embodiment of the present disclosure.

FIG. 3 is a schematic diagram illustrating the single pixel of FIG. 2, in accordance with an embodiment of the present disclosure.

FIG. 4A is a cross-section view of a source follower transistor from the pixel circuit of FIG. 3, in accordance with an embodiment of the present disclosure.

FIG. 4B is a cross-section view of the source follower while operating in saturation, in accordance with an embodiment of the present disclosure.

FIGS. 5A-5E are cross-section views of different stages in a fabrication process to form the source follower of FIG. 4A, in accordance with some embodiments of the present disclosure.

FIG. 6 illustrates an example computing platform that may include the image sensor of FIG. 1, in accordance with an embodiment of the present disclosure.

These and other features of the present embodiments will be understood better by reading the following detailed description, taken together with the figures herein described.

### DETAILED DESCRIPTION

Image sensors are disclosed. In an example, an image sensor includes a pixel array, with each pixel including a photodetector coupled to a readout circuit that includes a source follower amplifier. The source follower amplifier is implemented with a transistor configured with an asymmetric doping profile. For instance, according to some embodiments, the source follower transistor includes doped source and drain regions with a lightly doped drain (LDD) region adjacent to the source region, but no LDD region adjacent to the drain region. By not including the LDD region on the drain side of the source follower, parasitic capacitance across the gate-drain junction of the transistor is decreased, which provides a higher conversion gain of the pixel. During saturation operation of the source follower transistor, the inverted channel region beneath the gate pinches off short of the drain region, such that the lack of the LDD region adjacent to the drain does not cause a significant decrease to the resistance across the channel. Numerous variations and embodiments will be apparent in light of this disclosure.

### General Overview

As previously noted, there a number of non-trivial issues that remain with respect to designing image sensor circuits, particularly with respect to pixel design. For example, a complementary metal oxide semiconductor (CMOS) image sensor (CIS) includes a pixel array. A given pixel circuit of the array may include a photodetector coupled to a readout circuit. For such configurations, it can be challenging to achieve a high dynamic range and still maintain a high conversion gain from the charge received from the photodetector. The dynamic range of a photodetector generally refers to the maximum light intensity that can be received while remaining within a linear operation regime for the readout circuit. Accordingly, photodetector architectures with a higher dynamic range are capable of receiving higher intensity light that can be accurately represented as an electrical signal. The conversion gain generally refers to how much voltage can be generated per electron of charge from the photodetector. Parasitic effects within the readout circuit lower the conversion gain. For example, parasitic capacitance across the junctions of metal oxide semiconductor field effect transistor (MOSFET) devices can reduce the charge collection capability of the pixel, thus lowering the conversion gain of the pixel. To this end, a readout circuit that includes a source follower amplifier implemented with a MOSFET can have relatively low conversion gain.

Thus, and in accordance with an embodiment of the present disclosure, techniques are disclosed for designing a readout circuit with improved conversion gain. In an example, a given pixel of a pixel array includes a photodetector that provides its output to a readout circuit configured with a source follower transistor having an asymmetric doping profile that lowers parasitic capacitance and increases the conversion gain for the pixel. The readout circuit and photodetector may be part of a single pixel that is one pixel of an array of similarly designed pixels. In some cases, each pixel includes a photodetector and a dedicated readout circuit, while in other cases multiple photodetectors may share a readout circuit. The sensor array of pixels may be, for example, a CMOS image sensor (CIS) array or a charge coupled device (CCD) array, or a hybrid CMOS-CCD array having a CMOS readout circuit coupled with a CCD sensor. Other pixel-based imaging arrays may also benefit.

According to some embodiments, a pixel circuit (or more simply, a pixel) of a pixel array (e.g., in row-column format) includes a readout circuit coupled to a photodetector. A transfer gate transistor is coupled between the photodetector and a sensing node to transfer the charge from the photodetector to the sensing node. The sensing node may be coupled to one or more capacitors for temporarily storing the charge. According to some such embodiments, the sensing node is also coupled to the gate of a source follower transistor configured to generate a current signal based on the stored charge that is ultimately fed to a column amplifier or other amplifier element before being converted into a digital signal via an analog-to-digital converter (ADC).

According to some such embodiments, the source follower transistor includes a lightly doped drain (LDD) region adjacent to its source region, but does not include any LDD region adjacent to its drain region. As a result, the capacitance across the gate-source (GS) junction is relatively higher compared to the capacitance across the gate-drain (GD) junction. In some examples, the GS capacitance is at least 25%, 30%, 40%, 50%, or 75% higher compared to the GD capacitance. The reduced capacitance across the GD junction due to the lack of the corresponding LDD region reduces the overall parasitic capacitance of the readout circuit, thus increasing the conversion gain for the pixel. Note that pixel and pixel circuit may be used interchangeably herein, for ease and brevity of communication.

According to an example embodiment, an image sensor includes a plurality of pixels with at least one pixel of the plurality of pixels having a photodetector, a transfer gate having a first terminal coupled to an output of the photodetector, and a source follower field-effect transistor (FET). A second terminal of the transfer gate is coupled to a gate of the source follower FET. The source follower FET includes a first spacer on a first sidewall of the gate, a second spacer on a second sidewall of the gate opposite from the first sidewall, and a semiconductor layer under the gate. The semiconductor layer has an asymmetric doping profile that includes a first doped region having a first dopant type beneath the first spacer and beneath a portion of the gate adjacent to the first spacer along a top surface of the semiconductor layer and a second doped region adjacent to the first doped region and extending along the top surface of the semiconductor layer beneath the gate and beneath the second spacer. The second doped region has a second dopant type that is opposite from the first dopant type. In this manner, the source follower FET has an asymmetric doping profile under its gate structure and its spacers on the sidewalls of the gate structure.

According to another example embodiment, an image sensor includes a pixel array having at least one column of addressable pixels, a column amplifier coupled to the at least one column of addressable pixels, an analog-to-digital converter (ADC) coupled to the column amplifier, and a processor coupled to the ADC. The at least one column of addressable pixels includes at least one pixel circuit that includes a photodetector, a transfer gate having a first terminal coupled to an output of the photodetector, and a source follower FET having a gate coupled to a second terminal of the transfer gate. The source follower FET includes a first spacer on a first sidewall of the gate, a second spacer on a second sidewall of the gate opposite from the first sidewall, and an asymmetric doping profile under its gate. The doping profile may, for example, show a dopant concentration that gradually tapers or abruptly steps downward, or otherwise decreases, as it transitions along the bottom surface of the gate structure from the source region toward the drain region of the FET. For instance, the FET includes a first doped region having a given dopant type beneath the first spacer and beneath a first portion of the gate adjacent to the first spacer, and does not include a second doped region having the given dopant type beneath the second spacer and beneath a second portion of the gate adjacent to the second spacer.

According to another example embodiment, a pixel of a pixel array within an image sensor device includes a photodetector, a transfer gate having a first terminal coupled to an output of the photodetector, and source follower FET having a gate coupled to a second terminal of the transfer gate. The source follower FET includes a first spacer on a first sidewall of the gate, a second spacer on a second sidewall of the gate opposite from the first sidewall, a first source or drain region adjacent to the first spacer, and a second source or drain region adjacent to the second spacer. A first capacitance between the first source or drain region and the gate is at least 25% greater than a second capacitance between the second source or drain region and the gate.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### System Architecture

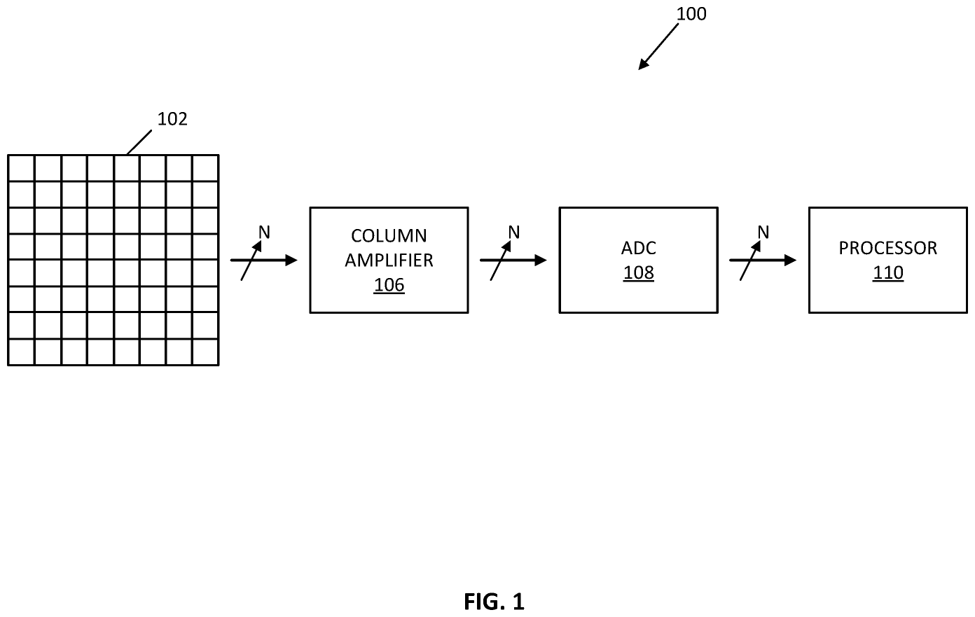

FIG. 1 is a block diagram of an example image sensor 100, according to some embodiments. Image sensor 100 may represent or be an integral part of imaging sensor device (e.g., CIS device, CCD device, or a hybrid CMOS-CCD device). In some embodiments, image sensor 100 may be configured for capturing different portions of the electromagnetic spectrum, such as visible light, ultraviolet radiation, infrared radiation, or x-rays, to name a few examples. Image sensor 100 may include a pixel array 102, a column amplifier 106, an ADC 108, and a processor 110. Each of the illustrated components may be included together on same printed circuit board (PCB) or together in a single chip package (e.g., a system-in-package or system-on-chip). In some other embodiments, any one or more of the elements may be provided in a separate chip package and/or on separate PCBs.

According to some embodiments, pixel array 102 includes a plurality of pixels arranged in a row-column format. Each pixel of pixel array 102 may have a similar architecture that includes a photodetector and a readout circuit. The photo detection area of each pixel on which incident radiation may impinge may vary from one embodiment to the next, but in some example cases has a physical size of around 1 μm×1 μm up to around 5 μm×5 μm. Likewise, the shape and lensing (if present) of the photo detection area (e.g., photo diode) can also vary from one example to the next, depending on factors such as desired fill factor of the array. According to some embodiments, each row of pixels may be coupled together via a common (shared) row-select line (e.g., a wordline), to provide separately addressable rows of pixels.

According to some embodiments, the outputs from N different columns of pixels are received by column amplifier 106. According to some embodiments, column amplifier 106 represents N separate column amplifiers with a given column amplifier configured to receive the output from a corresponding column of pixels from pixel array 102. In this way, a given row of pixels from pixel array 102 can be selected via a row-select line and simultaneously read out via the N column amplifiers 106. According to some embodiments, column amplifier 106 may include any type of amplifier configuration, such as any number of source follower FETs or operational amplifiers. In some embodiments, a single column amplifier 106 may be used in conjunction with a multiplexer to receive each of the N column outputs from pixel array 102.

According to some embodiments, the output(s) from column amplifier 106 is/are received by ADC 108. As noted above, ADC 108 may represent N different ADCs with a given ADC configured to receive the output from a corresponding column amplifier 106. ADC 108 may be any known type of ADC without limitation.

Processor 110 may be configured to receive the digitized signal from ADC 108 (or N digitized signals across N ADCs) and perform any number of operations with the signal(s). For example, processor 110 may receive the signal data from a given row of pixels of pixel array 102 and use the signal data to create an image or a portion of an image captured via pixel array 102. As used herein, the term “processor” may refer to any device or portion of a device that processes electronic data from registers and/or memory to transform that electronic data into other electronic data that may be stored in registers and/or memory. Processor 110 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, custom-built semiconductor, or any other suitable processing devices.

### Pixel Design

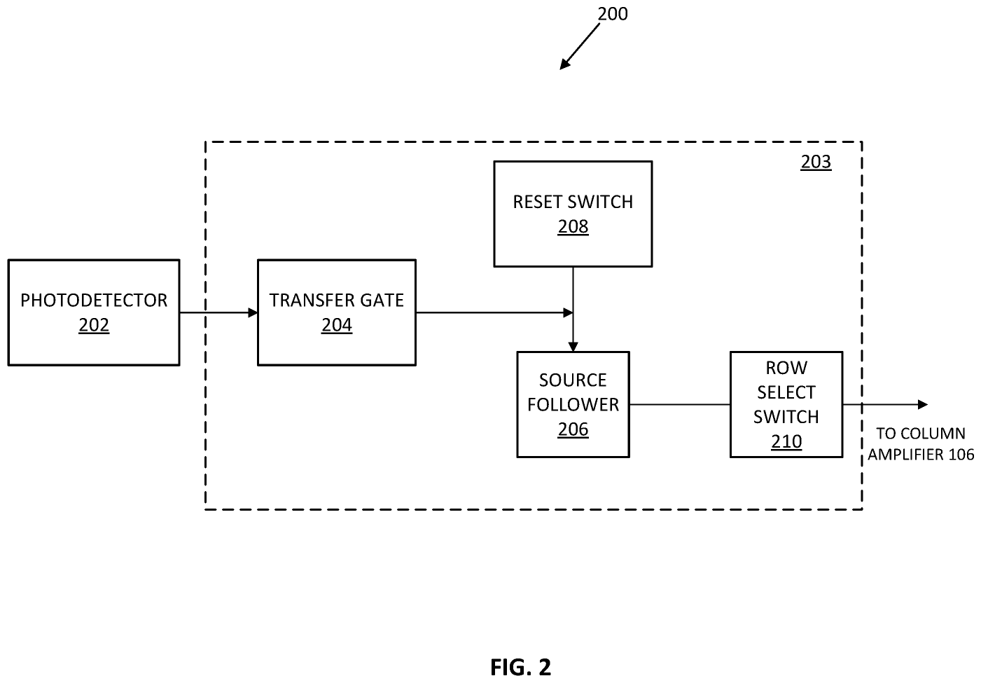

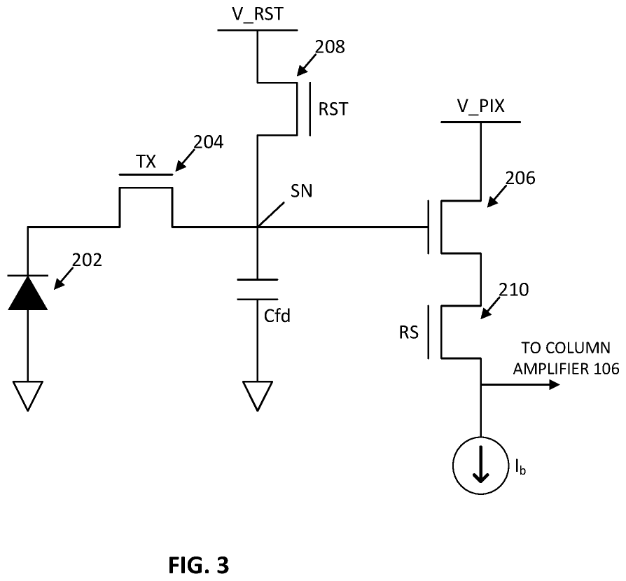

FIG. 2 illustrates a block diagram of a pixel 200 from pixel array 102 that includes a photodetector 202 and a readout circuit 203, according to some embodiments. FIG. 3 illustrates an example circuit schematic of the pixel block diagram from FIG. 2. Photodetector 202 may include any type of photosensitive design, such as a PN diode. Note that the term pixel may refer to a functional pixel circuit and not just the photo detection area of a given pixel.

According to some embodiments, readout circuit 203 includes a transfer gate 204 coupled to an output of photodetector 202. As described above, the active area of the photodetector 202 (e.g., the area which is sensitive to impinging light and generates a corresponding signal based on intensity of that light), as well as any lensing, can vary depending on the given application. Transfer gate 204 acts like a gatekeeper to the charge generated by photodetector 202 in response to a light input. In some embodiments, transfer gate 204 may include a single field effect transistor (FET), such as a p-doped or n-doped metal oxide semiconductor device (PMOS or NMOS), or any number of FETs that carry out a similar function.

Transfer gate 204 is configured to allow charge from photodetector 202 to pass on to a storage node SN coupled to a gate of a source follower 206. The charge may be stored across one or more capacitors coupled to storage node SN (e.g., Cfd), according to some embodiments. Source follower 206 may be implemented, for example, as a single source-follower NMOS or PMOS device, or as an operational amplifier. Source follower 206 may be powered, for example, via rail power V_PIX between about 2 V and about 2.5 V or some other suitable rail voltage. According to some embodiments, a reset switch 208 is also coupled to storage node SN (and the gate of source follower 206). Reset switch 208 may include a single field effect transistor (FET), such as a p-doped or n-doped metal oxide semiconductor device (PMOS or NMOS), or any number of FETs that carry out a similar function. A reset signal (RST) may be applied to a gate of reset switch 208 to apply a reset voltage (V_RST) to the storage node SN and clear it of any accumulated charge.

According to some embodiments, source follower 206 converts the stored charge from storage node SN into a corresponding photocurrent that is sent on to column amplifier 106 in response to the assertion of a row select signal RS at a row select switch 210. Row select switch 210 may have a gate or select input that is coupled to a common row-line (e.g., a wordline) with other pixels of the same row. Accordingly, when the current row is activated to read out from, row select switch 210 is activated and turned on to read out the output current to column amplifier 106. When the current row is not selected, row select switch 210 is not active and no signal is read out to column amplifier 106. Row select switch 210 may be implemented as an NMOS or PMOS device with the row-line RS coupled to the gate of the NMOS or PMOS device.

According to some embodiments, a high conversion gain can be achieved by maximizing the amount of charge stored across capacitor (or a network of capacitors) Cfd compared to charge lost to parasitic capacitance. One area where parasitic capacitance exists is across the gate-drain and gate-source junctions of source follower 206. The parasitic capacitance is increased due to the presence of lightly-doped drain (LDD) regions that extend partially beneath the gate. However, according to some embodiments, the parasitic capacitance can be reduced by eliminating the LDD region adjacent to the drain region of source follower 206.

### Source Follower Design

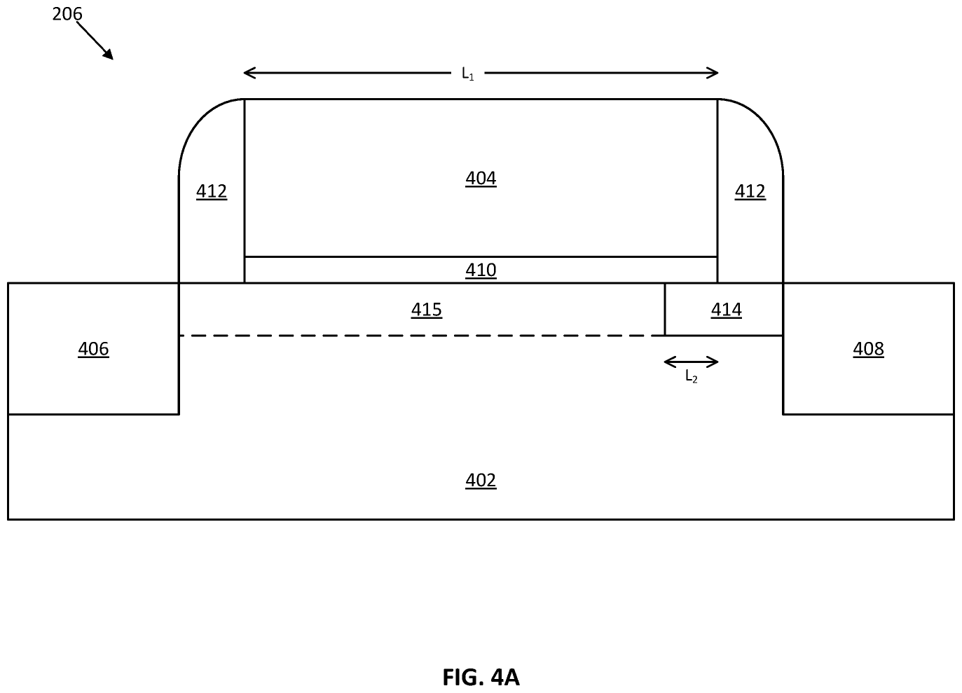

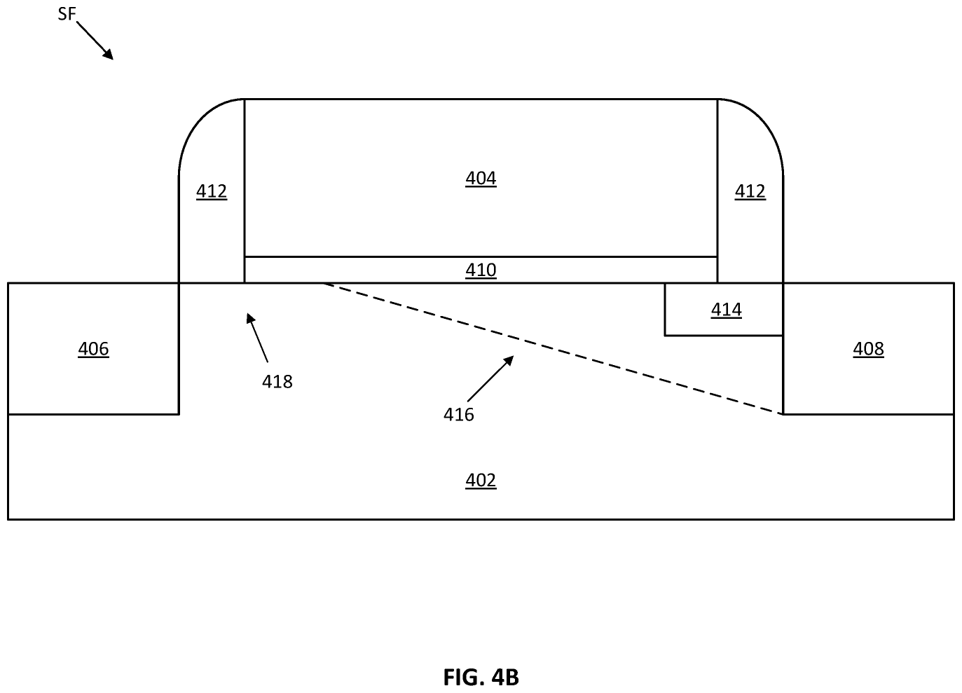

FIG. 4A illustrates an example cross-section of a MOSFET source follower 206, according to some embodiments. Source follower 206 is fabricated upon a substrate 402. According to some embodiments, substrate 402 includes any suitable semiconductor material, such as silicon, silicon germanium, or germanium. In some examples, substrate 402 may include any of various III-V semiconductor materials such as gallium arsenide or indium phosphide. Substrate 402 may be a silicon-on-insulator (SOI) substrate where substrate 402 represents a top semiconductor layer of the SOI substrate. In some examples, substrate 402 represents any semiconductor layer having a total thickness of less than 1 micrometer, less than 2 micrometers, or less than 10 micrometers.

Source follower 206 includes a gate 404, drain region 406, and source region 408. It should be understood that both drain region 406 and source region 408 do not act as a MOSFET drain and source unless the MOSFET is in operation, but the regions are identified herein as being a drain and source for clarity. Gate 404 may include polysilicon or a metal material, such as tungsten. In the case of polysilicon, gate 404 may be doped to increase its conductivity, as will be discussed in more detail herein. Gate 404 may have a length L₁ between about 0.3 μm and 0.5 μm.

Each of drain region 406 and source region 408 may be doped portions of substrate 402 near opposite sides of gate 404. In some embodiments, source follower 206 is an NMOS device, and drain region 406 and source region 408 include n-type dopants. Drain region 406 and source region 408 may each include an n-type dopant concentration between 1×10¹⁵ and 5×10¹⁵ cm⁻³. Example n-type dopants include phosphorous or arsenic. Substrate 402 in the area surrounding drain region 406 and source region 408 may be doped with the opposite dopant type (p-type dopants), such as boron.

A gate dielectric 410 is present between gate 404 and substrate 402, according to some embodiments. Gate dielectric 410 may extend only across the same length as gate 404, or may extend beyond gate 404. Gate dielectric 410 may be an oxide material of substrate 402 (e.g., silicon dioxide), or may include any number of other dielectric layers. In some examples, gate dielectric 410 includes one or more high-k dielectric materials, such as hafnium oxide.

According to some embodiments, spacer structures 412 are present on sidewalls of gate 404. Spacer structures 412 may be provided to set the dopant locations for drain region 406 and source region 408, as will be discussed in more detail herein. Spacer structures 412 may be any suitable dielectric material, such as silicon nitride or silicon oxynitride.

According to some embodiments, an LDD region 414 is provided directly adjacent to source region 408 and beneath spacer structure 412 and at least a portion of gate 404. LDD region 414 may overlap with gate 404 for a distance L₂ between about 30 nm and about 50 nm. LDD region 414 may be provided to lower the resistance across the channel between drain region 406 and source region 408 during operation of source follower 206. LDD region 414 may be a doped region having the same dopant type as source region 408, but a lower dopant concentration compared to source region 408. In some examples, LDD region 414 has a dopant concentration of n-type dopants between about 1×10¹² and 1×10¹³ cm⁻³. The presence of LDD region 414 increases the parasitic capacitance between gate 404 and source region 408 (e.g., by extending a conductive region closer to gate 404). Typically, such LDD regions are provided next to each of source region 408 and drain region 406 to reduce the resistance of the channel. However, in accordance with some embodiments, there is no corresponding LDD region adjacent to drain region 406, creating an asymmetric doping profile across the length of the transistor. According to some embodiments, another doped region 415 adjacent to LDD region 414 extends beneath gate 404 and spacer structure 412 adjacent to drain region 406 along the top surface of substrate 402. Doped region 415 may have the same dopant type and concentration as a remainder of substrate 402. For example, doped region 415 may include the opposite dopant type from LDD region 414 (e.g., doped region 415 includes p-type dopants).

By omitting the LDD region adjacent to drain region 406, the parasitic capacitance between gate 404 and drain 406 is reduced compared to a situation that includes an LDD region adjacent to drain region 406. According to some embodiments, the capacitance between gate 404 and source region 408 is at least 25%, 30%, 40%, 50%, or 75% higher compared to the capacitance between gate 404 and drain region 406.

FIG. 4B illustrates source follower 206 during a saturation mode of operation, according to some embodiments. When operating in saturation mode, the channel region 416 of minority carriers pinches off before drain region 406. A strong electric field remains in the depleted region 418 between the pinched off channel region 416 and drain region 406 to accelerate the carriers across depleted region 418. Since channel region 416 is pinched off prior to drain region 406 during saturation, the omission of an LDD region adjacent to drain region 406 does not significantly impact the resistance across the channel between source region 408 and drain region 406.

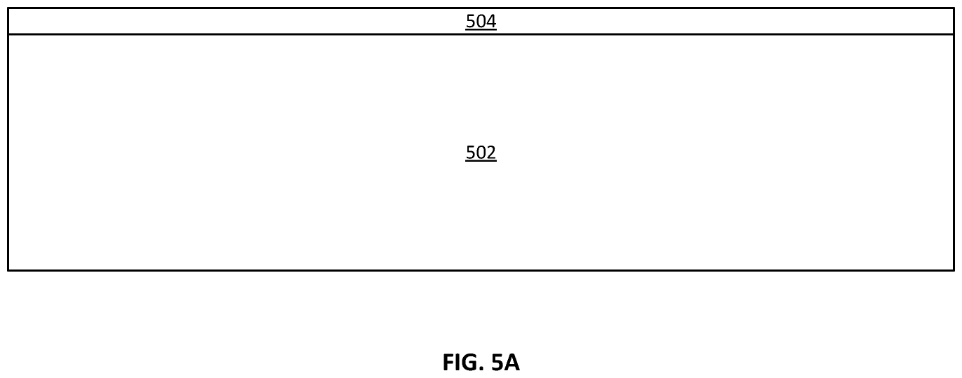

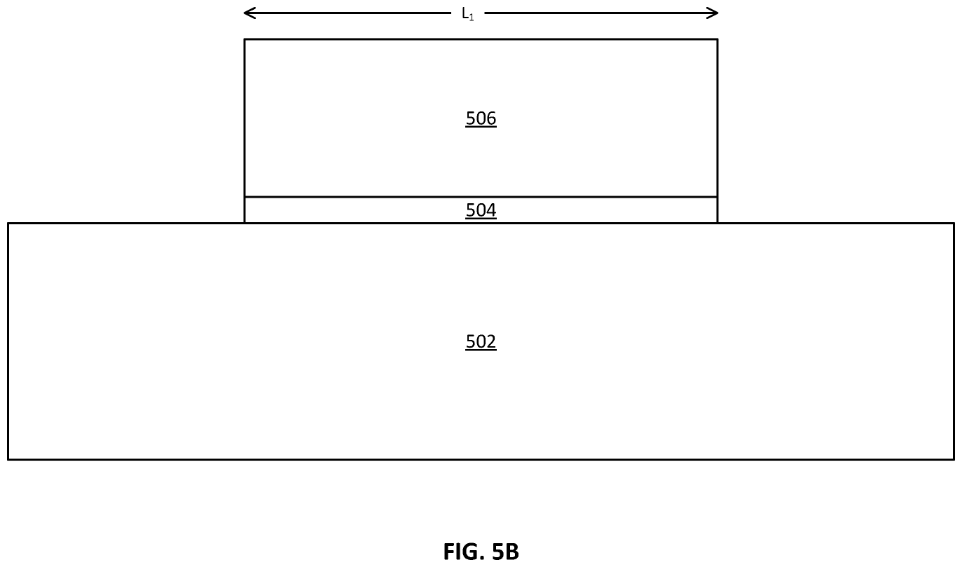

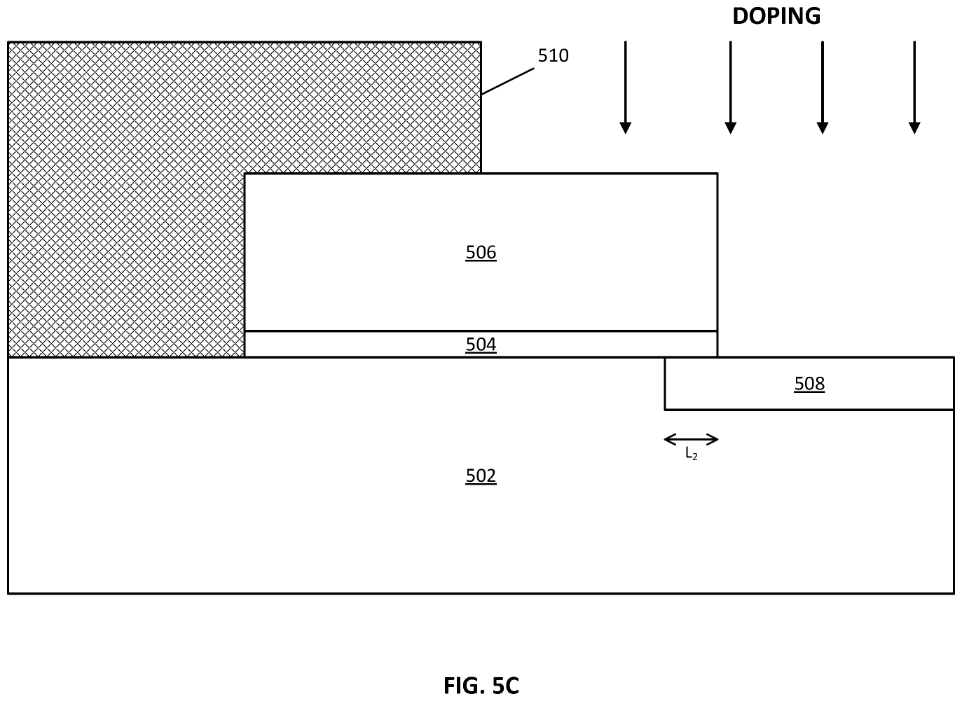

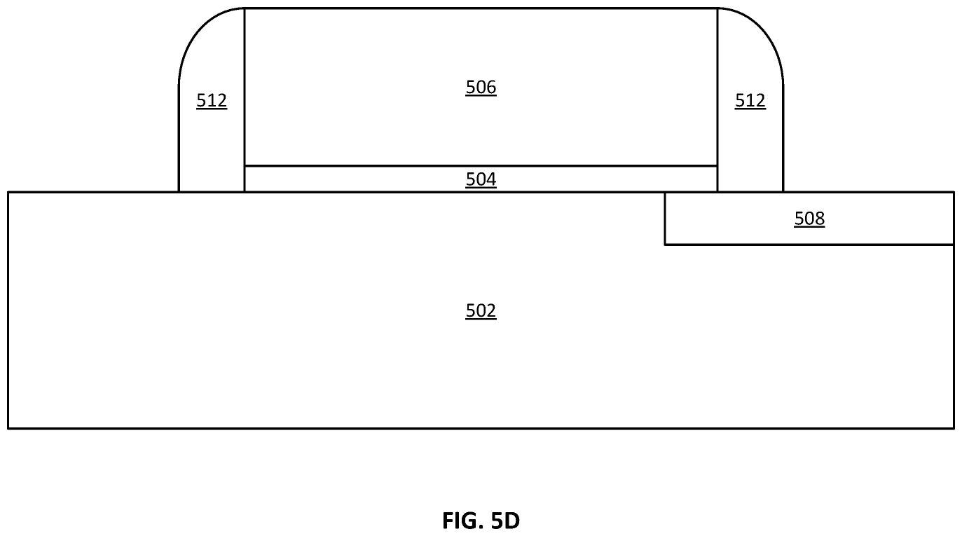

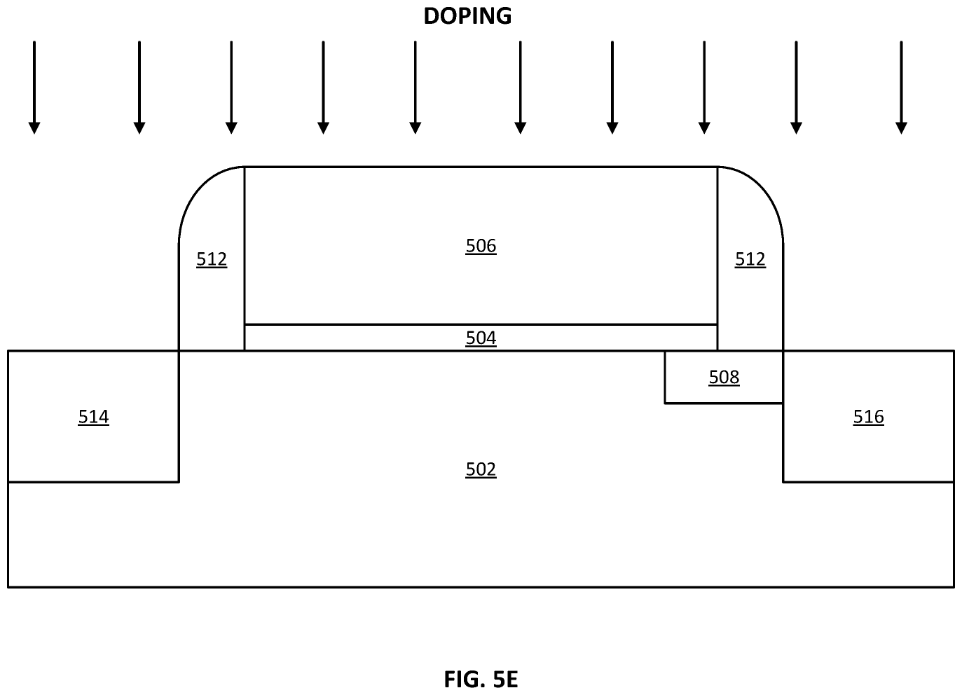

FIGS. 5A-5E include cross-sectional views that collectively illustrate an example process for forming a source follower transistor with an LDD region on only side of the gate, in accordance with an embodiment of the present disclosure. Each of the figures shows an example structure that results from the process flow up to that point in time, so the depicted structure evolves as the process flow continues, culminating in the structure shown in FIG. 5E, which is similar to the structure shown in FIG. 4A. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated.

FIG. 5A illustrates a substrate 502 along with a dielectric layer 504 on a top surface of substrate 502, according to some embodiments. Substrate 502 may be similar to substrate 402 discussed above. Dielectric layer 504 may be an oxide of substrate 502 (e.g., silicon dioxide), and may be formed via thermal oxidation of substrate 502. Other techniques may be used as well to form dielectric layer 504. According to some embodiments, dielectric layer 504 has a thickness between about 5 nm and about 20 nm.

FIG. 5B depicts the cross-section view of the structure shown in FIG. 5A, following the formation of a gate 506, according to some embodiments. As noted above, gate 506 may include polysilicon or any suitable metal material. According to some embodiments, gate 506 is lithographically patterned after being deposited to a gate length L₁ between about 0.3 μm and 0.5 μm. In some examples, the same process used to pattern the gate (e.g., an anisotropic etching process) may also pattern dielectric layer 504, such that dielectric layer 504 only remains beneath gate 506.

FIG. 5C depicts the cross-section view of the structure shown in FIG. 5B, following a doping process to form LDD region 508, according to some embodiments. A mask structure 510 is patterned to cover one side of gate 506 to prevent doping substrate 502 adjacent to that side of gate 506. Mask structure 510 may be a hard mask layer, such as a dielectric material or carbon hard mask (CHM), or a photoresist. Mask structure 510 may be patterned using any suitable lithography technique to expose one side of gate 506 while covering the opposite side of gate 506. Any portion of gate 506 may also be covered by mask structure 510. The presence of mask structure 510 prevents an LDD region from being formed on the left side of gate 506.

According to some embodiments, a doping process is performed to form LDD region 508 within substrate 502. In some examples, dopants are introduced into substrate 502 using an ion implantation or diffusion process. In the case of an NMOS device, phosphorus or arsenic dopants are introduced into substrate 502 at a concentration between about 1×10¹² and 1×10¹³ cm⁻³. Note that the doping process is not perfectly directional such that some dopants will bleed under gate 506 by a distance L₂, according to some embodiments. The distance L₂ may be between about 30 nm and about 50 nm.

FIG. 5D depicts the cross-section view of the structure shown in FIG. 5C, following the formation of spacer structures 512, according to some embodiments. Spacer structures 512 may be formed from a dielectric material that is blanket deposited across the whole structure and then etched back to leave behind the dielectric material on the sidewalls of gate 506. As noted above, spacer structures 512 may include silicon nitride or silicon oxynitride. An anisotropic etching process, such as reactive ion etching (RIE), may be used to etch back the deposited dielectric material, which removes the material from all horizontal surfaces, but leaves the material along structure sidewalls. The width of spacer structures 512 roughly dictates the distance that the source and drain regions will be spaced from gate 506.

FIG. 5E depicts the cross-section view of the structure shown in FIG. 5D, following a second doping process to form drain region 514 and source region 516, according to some embodiments. A higher dopant concentration of n-type dopants (in the example of an NMOS device) may be used compared to the dopant process used to form LDD region 508. In some embodiments, an ion implantation or diffusion process is used to form drain region 514 and source region 516 having a dopant concentration between about 1×10¹⁵ and 5×10¹⁵ cm⁻³. The exposed gate 506 may also be doped to further increase the conductivity of gate 506.

According to some embodiments, drain region 514 and source region 516 are spaced from gate 506 by roughly the width of spacer structures 512. Some portion of drain region 514 and source region 516 may extend beneath spacer structures 512. According to some embodiments, the masked doping procedure used to form LDD region 508 yields no corresponding LDD region adjacent to drain region 514. The omission of any LDD region adjacent to drain region 514 effectively increases the distance between the conductive elements of gate 506 and drain region 514, thus lowering the parasitic capacitance across the gate-drain junction.

### Example Computing Platform

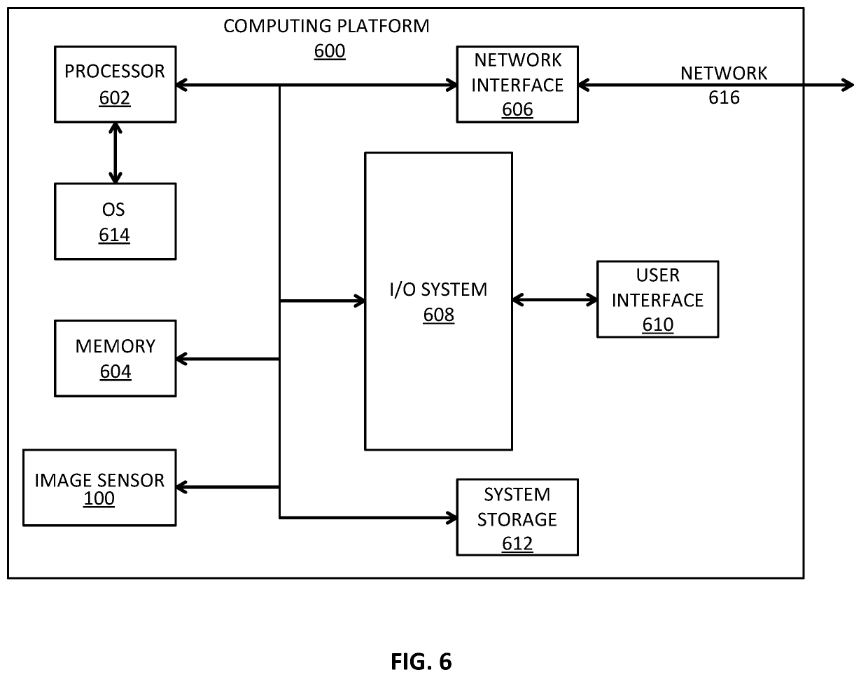

FIG. 6 illustrates an example computing platform 600 that interfaces with image sensor 100, configured in accordance with certain embodiments of the present disclosure. In some embodiments, computing platform 600 may host, or otherwise be incorporated into a personal computer, workstation, server system, laptop computer, ultra-laptop computer, tablet, touchpad, portable computer, handheld computer, palmtop computer, personal digital assistant (PDA), cellular telephone, combination cellular telephone and PDA, smart device (for example, smartphone or smart tablet), mobile internet device (MID), messaging device, data communication device, imaging device, wearable device, embedded system, and so forth. Any combination of different devices may be used in certain embodiments.

In some embodiments, computing platform 600 may comprise any combination of a processor 602, a memory 604, image sensor 100, a network interface 606, an input/output (I/O) system 608, a user interface 610, and a storage system 612. In some embodiments, one or more components of image sensor 100 are implemented as part of processor 602. As can be further seen, a bus and/or interconnect is also provided to allow for communication between the various components listed above and/or other components not shown. Computing platform 600 can be coupled to a network 616 through network interface 606 to allow for communications with other computing devices, platforms, or resources. Other componentry and functionality not reflected in the block diagram of FIG. 6 will be apparent in light of this disclosure, and it will be appreciated that other embodiments are not limited to any particular hardware configuration.

Processor 602 can be any suitable processor and may include one or more coprocessors or controllers to assist in control and processing operations associated with computing platform 600. In some embodiments, processor 602 may be implemented as any number of processor cores. The processor (or processor cores) may be any type of processor, such as, for example, a micro-processor, an embedded processor, a digital signal processor (DSP), a graphics processor (GPU), a network processor, a field programmable gate array or other device configured to execute code. The processors may be multithreaded cores in that they may include more than one hardware thread context (or “logical processor”) per core.

Memory 604 can be implemented using any suitable type of digital storage including, for example, flash memory and/or random access memory (RAM). In some embodiments, memory 604 may include various layers of memory hierarchy and/or memory caches as are known to those of skill in the art. Memory 604 may be implemented as a volatile memory device such as, but not limited to, a RAM, dynamic RAM (DRAM), or static RAM (SRAM) device. Storage system 612 may be implemented as a non-volatile storage device such as, but not limited to, one or more of a hard disk drive (HDD), a solid-state drive (SSD), a universal serial bus (USB) drive, an optical disk drive, tape drive, an internal storage device, an attached storage device, flash memory, battery backed-up synchronous DRAM (SDRAM), and/or a network accessible storage device. In some embodiments, storage system 612 may comprise technology to increase the storage performance enhanced protection for valuable digital media when multiple hard drives are included.

Processor 602 may be configured to execute an Operating System (OS) 614 which may comprise any suitable operating system, such as Google Android (Google Inc., Mountain View, CA), Microsoft Windows (Microsoft Corp., Redmond, WA), Apple OS X (Apple Inc., Cupertino, CA), Linux, or a real-time operating system (RTOS). As will be appreciated in light of this disclosure, the techniques provided herein can be implemented without regard to the particular operating system provided in conjunction with computing platform 600, and therefore may also be implemented using any suitable existing or subsequently-developed platform.

Network interface 606 can be any appropriate network chip or chipset which allows for wired and/or wireless connection between other components of computing platform 600 and/or network 616, thereby enabling computing platform 600 to communicate with other local and/or remote computing systems, servers, cloud-based servers, and/or other resources. Wired communication may conform to existing (or yet to be developed) standards, such as, for example, Ethernet. Wireless communication may conform to existing (or yet to be developed) standards, such as, for example, cellular communications including LTE (Long Term Evolution), Wireless Fidelity (Wi-Fi), Bluetooth, and/or Near Field Communication (NFC). Exemplary wireless networks include, but are not limited to, wireless local area networks, wireless personal area networks, wireless metropolitan area networks, cellular networks, and satellite networks.

I/O system 608 may be configured to interface between various I/O devices and other components of computing platform 600. I/O devices may include, but not be limited to, a user interface 610. User interface 610 may include devices (not shown) such as a display element, touchpad, keyboard, mouse, and speaker, etc. I/O system 608 may include a graphics subsystem configured to perform processing of images for rendering on a display element. Graphics subsystem may be a graphics processing unit or a visual processing unit (VPU), for example. An analog or digital interface may be used to communicatively couple graphics subsystem and the display element. For example, the interface may be any of a high definition multimedia interface (HDMI), DisplayPort, wireless HDMI, and/or any other suitable interface using wireless high definition compliant techniques. In some embodiments, the graphics subsystem could be integrated into processor 602 or any chipset of computing platform 600.

It will be appreciated that in some embodiments, the various components of the computing platform 600 may be combined or integrated in a system-on-a-chip (SoC) architecture. In some embodiments, the components may be hardware components, firmware components, software components or any suitable combination of hardware, firmware or software.

In various embodiments, computing platform 600 may be implemented as a wireless system, a wired system, or a combination of both. When implemented as a wireless system, computing platform 600 may include components and interfaces suitable for communicating over a wireless shared media, such as one or more antennae, transmitters, receivers, transceivers, amplifiers, filters, control logic, and so forth. An example of wireless shared media may include portions of a wireless spectrum, such as the radio frequency spectrum and so forth. When implemented as a wired system, computing platform 600 may include components and interfaces suitable for communicating over wired communications media, such as input/output adapters, physical connectors to connect the input/output adaptor with a corresponding wired communications medium, a network interface card (NIC), disc controller, video controller, audio controller, and so forth. Examples of wired communications media may include a wire, cable metal leads, printed circuit board (PCB), backplane, switch fabric, semiconductor material, twisted pair wire, coaxial cable, fiber optics, and so forth.

Unless specifically stated otherwise, it may be appreciated that terms such as “processing,” “computing,” “calculating,” “determining,” or the like refer to the action and/or process of a computer or computing system, or similar electronic computing device, that manipulates and/or transforms data represented as physical quantities (for example, electronic) within the registers and/or memory units of the computer system into other data similarly represented as physical quantities within the registers, memory units, or other such information storage transmission or displays of the computer system. The embodiments are not limited in this context.

The terms “circuit” or “circuitry,” as used in any embodiment herein, may comprise, for example, singly or in any combination, hardwired circuitry, programmable circuitry such as computer processors comprising one or more individual instruction processing cores, state machine circuitry, and/or firmware that stores instructions executed by programmable circuitry. The circuitry may include a processor and/or controller configured to execute one or more instructions to perform one or more operations described herein. The instructions may be embodied as, for example, an application, software, firmware, etc. configured to cause the circuitry to perform any of the aforementioned operations. Software may be embodied as a software package, code, instructions, instruction sets and/or data recorded on a computer-readable storage device. Software may be embodied or implemented to include any number of processes, and processes, in turn, may be embodied or implemented to include any number of threads, etc., in a hierarchical fashion. Firmware may be embodied as code, instructions or instruction sets and/or data that are hard-coded (e.g., nonvolatile) in memory devices. The circuitry may, collectively or individually, be embodied as circuitry that forms part of a larger system, for example, an integrated circuit (IC), an application-specific integrated circuit (ASIC), a system on-chip (SoC), desktop computers, laptop computers, tablet computers, servers, smart phones, etc. Other embodiments may be implemented as software executed by a programmable control device. As described herein, various embodiments may be implemented using hardware elements, software elements, or any combination thereof. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth.

Various embodiments may be implemented using hardware elements, software elements, or a combination of both. Examples of hardware elements may include processors, microprocessors, circuits, circuit elements (for example, transistors, resistors, capacitors, inductors, and so forth), integrated circuits, ASICs, programmable logic devices, digital signal processors, FPGAs, GPUs, logic gates, registers, semiconductor devices, chips, microchips, chipsets, and so forth. Examples of software may include software components, programs, applications, computer programs, application programs, system programs, machine programs, operating system software, middleware, firmware, software modules, routines, subroutines, functions, methods, procedures, software interfaces, application program interfaces, instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power level, heat tolerances, processing cycle budget, input data rates, output data rates, memory resources, data bus speeds, and other design or performance constraints.

### Further Example Embodiments

The following examples pertain to further embodiments, from which numerous permutations and configurations will be apparent.

Example 1 is an image sensor that includes a plurality of pixels with at least one pixel of the plurality of pixels having a photodetector, a transfer gate having a first terminal coupled to an output of the photodetector, and a source follower field-effect transistor (FET). A second terminal of the transfer gate is coupled to a gate of the source follower FET. The source follower FET includes a first spacer on a first sidewall of the gate, a second spacer on a second sidewall of the gate opposite from the first sidewall, and a semiconductor layer under the gate. The semiconductor layer has an asymmetric doping profile that includes a first doped region having a first dopant type beneath the first spacer and beneath a portion of the gate adjacent to the first spacer along a top surface of the semiconductor layer and a second doped region adjacent to the first doped region and extending along the top surface of the semiconductor layer beneath the gate and beneath the second spacer. The second doped region has a second dopant type that is opposite from the first dopant type.

Example 2 includes the image sensor of Example 1, wherein the first doped region comprises n-type dopants.

Example 3 includes the image sensor of Example 1 or 2, wherein the source follower FET further comprises a first source or drain region adjacent to the first doped region and the first spacer, and a second source or drain region adjacent to the second spacer.

Example 4 includes the image sensor of Example 3, wherein the first source or drain region and the second source or drain region comprise a higher dopant concentration of the first dopant type compared to the first doped region.

Example 5 includes the image sensor of Example 3 or 4, wherein a first capacitance between the first source or drain region and the gate is at least 25% greater than a second capacitance between the second source or drain region and the gate.

Example 6 includes the image sensor of Example 3 or 4, wherein a first capacitance between the first source or drain region and the gate is at least 50% greater than a second capacitance between the second source or drain region and the gate.

Example 7 includes the image sensor of any one of Examples 1-6, further comprising a reset switch coupled to the second terminal of the transfer gate.

Example 8 includes the image sensor of any one of Examples 1-7, wherein the gate has a length between about 0.3 and 0.5 micrometers between the first spacer and the second spacer.

Example 9 includes the image sensor of any one of Examples 1-8, wherein the first portion of the gate is between about 30 nm and about 50 nm.

Example 10 is an image sensor that includes a pixel array having at least one column of addressable pixels, a column amplifier coupled to the at least one column of addressable pixels, an analog-to-digital converter (ADC) coupled to the column amplifier, and a processor coupled to the ADC. The at least one column of addressable pixels includes at least one pixel circuit that includes a photodetector, a transfer gate having a first terminal coupled to an output of the photodetector, and a source follower FET having a gate coupled to a second terminal of the transfer gate. The source follower FET includes a first spacer on a first sidewall of the gate, a second spacer on a second sidewall of the gate opposite from the first sidewall, and a first doped region having a given dopant type beneath the first spacer and beneath a first portion of the gate adjacent to the first spacer. The source follower FET does not include a second doped region having the given dopant type beneath the second spacer and beneath a second portion of the gate adjacent to the second spacer.

Example 11 includes the image sensor of Example 10, wherein the first doped region comprises n-type dopants.

Example 12 includes the image sensor of Example 10 or 11, wherein the source follower FET further comprises a first source or drain region adjacent to the first doped region and the first spacer, and a second source or drain region adjacent to the second spacer.

Example 13 includes the image sensor of Example 12, wherein the first source or drain region and the second source or drain region comprise a higher dopant concentration of the given dopant type compared to the first doped region.

Example 14 includes the image sensor of Example 12 or 13, wherein a first capacitance between the first source or drain region and the gate is at least 25% greater than a second capacitance between the second source or drain region and the gate.

Example 15 includes the image sensor of Example 12 or 13, wherein a first capacitance between the first source or drain region and the gate is at least 50% greater than a second capacitance between the second source or drain region and the gate.

Example 16 includes the image sensor of any one of Examples 10-15, wherein the at least one pixel further comprises a reset switch coupled to the second terminal of the transfer gate.

Example 17 includes the image sensor of any one of Examples 10-16, wherein the gate has a length between about 0.3 and 0.5 micrometers between the first spacer and the second spacer.

Example 18 includes the image sensor of any one of Examples 10-17, wherein the first portion of the gate is between about 30 nm and about 50 nm.

Example 19 is a pixel of a pixel array within an imaging sensor device. The pixel includes a photodetector, a transfer gate having a first terminal coupled to an output of the photodetector, and source follower FET having a gate coupled to a second terminal of the transfer gate. The source follower FET includes a first spacer on a first sidewall of the gate, a second spacer on a second sidewall of the gate opposite from the first sidewall, a first source or drain region adjacent to the first spacer, and a second source or drain region adjacent to the second spacer. A first capacitance between the first source or drain region and the gate is at least 25% greater than a second capacitance between the second source or drain region and the gate.

Example 20 includes the pixel of Example 19, wherein the source follower FET further comprises a doped region having a same dopant type as the first and second source or drain regions, the doped region being beneath the first spacer and beneath a first portion of the gate adjacent to the first spacer.

Example 21 includes the pixel of Example 20, wherein the doped region comprises n-type dopants.

Example 22 includes the pixel of Example 20 or 21, wherein the first source or drain region and the second source or drain region comprise a higher dopant concentration compared to the doped region.

Example 23 includes the pixel of any one of Examples 20-22, wherein the gate has a length between about 0.3 and 0.5 micrometers between the first spacer and the second spacer.

Example 24 includes the pixel of Example 23, wherein the first portion of the gate is between about 30 nm and about 50 nm.

Example 25 includes the pixel of any one of Examples 19-24, wherein the first capacitance between the first source or drain region and the gate is at least 50% greater than the second capacitance between the second source or drain region and the gate.

Example 26 includes the pixel of any one of Examples 19-25, further comprising a reset switch coupled to the second terminal of the transfer gate.

Numerous specific details have been set forth herein to provide a thorough understanding of the embodiments. It will be understood by an ordinarily-skilled artisan, however, that the embodiments may be practiced without these specific details. In other instances, well known operations, components and circuits have not been described in detail so as not to obscure the embodiments. It can be appreciated that the specific structural and functional details disclosed herein may be representative and do not necessarily limit the scope of the embodiments. In addition, although the subject matter has been described in language specific to structural features and/or methodological acts, it is to be understood that the subject matter defined in the appended claims is not necessarily limited to the specific features or acts described herein. Rather, the specific features and acts described herein are disclosed as example forms of implementing the claims.

What is claimed is:

1. An image sensor, comprising:
a plurality of pixels, wherein at least one pixel of the plurality of pixels comprises
a photodetector;
a transfer gate having a first terminal coupled to an output of the photodetector; and
a source follower field-effect transistor (FET) having a gate coupled to a second terminal of the transfer gate, wherein the source follower FET comprises
a first spacer on a first sidewall of the gate,
a second spacer on a second sidewall of the gate opposite from the first sidewall, and
a semiconductor layer under the gate, the semiconductor layer having an asymmetric doping profile comprising a first doped region having a first dopant type beneath the first spacer and beneath a portion of the gate adjacent to the first spacer along a top surface of the semiconductor layer and a second doped region adjacent to the first doped region and extending along the top surface of the semiconductor layer beneath the gate and beneath the second spacer, wherein the second doped region has a second dopant type that is opposite from the first dopant type.

2. The image sensor of claim 1, wherein the first doped region comprises n-type dopants.

3. The image sensor of claim 1, wherein the source follower FET further comprises a first source or drain region adjacent to the first doped region and the first spacer, and a second source or drain region adjacent to the second spacer.

4. The image sensor of claim 3, wherein the first source or drain region and the second source or drain region comprise a higher dopant concentration of the first dopant type compared to the first doped region.

5. The image sensor of claim 3, wherein a first capacitance between the first source or drain region and the gate is at least 25% greater than a second capacitance between the second source or drain region and the gate.

6. The image sensor of claim 1, wherein the gate has a length between about 0.3 and 0.5 micrometers between the first spacer and the second spacer.

7. The image sensor of claim 1, wherein the first portion of the gate is between about 30 nm and about 50 nm.

8. An image sensor, comprising:
a pixel array having at least one column of addressable pixels;
a column amplifier coupled to the at least one column of addressable pixels;
an analog-to-digital converter (ADC) coupled to the column amplifier; and
a processor coupled to the ADC;
wherein the at least one column of addressable pixels includes at least one pixel that comprises
a photodetector,
a transfer gate having a first terminal coupled to an output of the photodetector, and
a source follower FET having a gate coupled to a second terminal of the transfer gate, wherein the source follower FET comprises
a first spacer on a first sidewall of the gate,
a second spacer on a second sidewall of the gate opposite from the first sidewall, and
a first doped region having a given dopant type beneath the first spacer and beneath a first portion of the gate adjacent to the first spacer, wherein the source follower FET does not include a second doped region having the given dopant type beneath the second spacer and beneath a second portion of the gate adjacent to the second spacer.

9. The image sensor of claim 8, wherein the first doped region comprises n-type dopants.

10. The image sensor of claim 8, wherein the source follower FET further comprises a first source or drain region adjacent to the first doped region and the first spacer, and a second source or drain region adjacent to the second spacer.

11. The image sensor of claim 10, wherein the first source or drain region and the second source or drain region comprise a higher dopant concentration of the given dopant type compared to the first doped region.

12. The image sensor of claim 10, wherein a first capacitance between the first source or drain region and the gate is at least 25% greater than a second capacitance between the second source or drain region and the gate.

13. The image sensor of claim 8, wherein the first portion of the gate is between about 30 nm and about 50 nm.

14. A pixel of a pixel array within an imaging sensor device, the pixel comprising:
a photodetector;
a transfer gate having a first terminal coupled to an output of the photodetector; and
a source follower FET having a gate coupled to a second terminal of the transfer gate, wherein the source follower FET comprises
a first spacer on a first sidewall of the gate,
a second spacer on a second sidewall of the gate opposite from the first sidewall,
a first source or drain region adjacent to the first spacer, and
a second source or drain region adjacent to the second spacer,
wherein a first capacitance between the first source or drain region and the gate is at least 25% greater than a second capacitance between the second source or drain region and the gate.

15. The pixel of claim 14, wherein the source follower FET further comprises a doped region having a same dopant type as the first and second source or drain regions, the doped region being beneath the first spacer and beneath a first portion of the gate adjacent to the first spacer.

16. The pixel of claim 15, wherein the doped region comprises n-type dopants.

17. The pixel of claim 15, wherein the first source or drain region and the second source or drain region comprise a higher dopant concentration compared to the doped region.

18. The pixel of claim 15, wherein the gate has a length between about 0.3 and 0.5 micrometers between the first spacer and the second spacer.

19. The pixel of claim 18, wherein the first portion of the gate is between about 30 nm and about 50 nm.

20. The pixel of claim 14, wherein the first capacitance between the first source or drain region and the gate is at least 50% greater than the second capacitance between the second source or drain region and the gate.
